(19) United States
(12) Patent Application Publication
(10) Pub. No.: US 2026/0100570 A1
(43) Pub. Date: Apr. 9, 2026

(54) USER INTERFACE

(71) Applicant: Atom Power, Inc., Huntersville, NC (US)

(72) Inventors: Matthew Deese, Huntersville, NC (US); Andrew Nicholas Dames, Cambridge (GB); Paul Jeffrey Dunaway, Cambridge (GB); Zijian Zhao, Cambridge (GB)

(21) Appl. No.: 18/907,003

(22) Filed: Oct. 4, 2024

(51) Int. Cl. H02H 3/08; H02H 3/04; H03K 17/082

(52) U.S. Cl. CPC H02H 3/08; H02H 3/04; H03K 17/0822

(57) ABSTRACT

A circuit breaker includes an air gap device having contacts that can be opened and closed to interrupt or connect electrical power to a downstream load, a solenoid coupled to the air gap device and configured to actuate the contacts, and a firmware state machine having at least four unique states (STANDBY, TRIP, OFF, ON) that controls the solenoid and opens/closes the contacts based on inputs received from a user interface element. The user interface element has a single lever with at least two positions and sends signals to the firmware state machine indicating the position of the lever. A sensor coupled to the user interface element detects when the lever is moved, sending a signal to the firmware state machine. At least one FET switch is coupled between the air gap device and the downstream load in response to a signal from the firmware state machine.

### FIELD OF THE DISCLOSURE

The present disclosure relates to electronic circuit breakers and more particularly to a circuit breaker having a firmware state machine that controls the actuation of an air gap device based on inputs received from a user interface element.

### BACKGROUND

Although there have been significant optimization efforts and design modifications, the architecture for miniature circuit breakers of the mechanical type has been more or less the same for 100 years. A 1927 U.S. Pat. No. 1,629,640 details sprung contacts which can be separated by a thermal trip and a magnetic trip and can be reset via a user-accessible button. It is typical for today's circuit breakers to provide an OFF state in addition to the ON and TRIP states offered by the first design—this initiated by the user changing the position of a lever, which can also facilitate a lockout tagout.

Because solid-state circuit breakers (SSCBs) do not have need for a thermal or magnetic trip element, replacing them with a variety of electronic circuitry (still containing an electronically and user-controlled air gap device for galvanic isolation), significant differences in SSCB mechanical design constraints compared with mechanical breakers necessitates radical changes to product architecture to fit the miniature circuit breaker form factor. These changes also present unique challenges and questions, such as how to replicate the existing/typical miniature circuit breaker user interface with a solid-state architecture, and if a redesigned user interface could better suit SSCBs while meeting functional requirements and providing an intuitive user experience.

### SUMMARY

The present disclosure provides a circuit breaker that includes an air gap device having contacts that can be opened and closed to interrupt or connect electrical power to a downstream load, a solenoid coupled to the air gap device and configured to actuate the air gap device, and a firmware state machine having at least four unique states (STANDBY, TRIP, OFF, ON) that controls the solenoid and opens/closes the contacts of the air gap device based on inputs received from a user interface element. The user interface element has a single lever with two positions (up, down or left, right depending on orientation of breaker), and sends signals to the firmware state machine indicating the position of the lever. A microswitch or other sensor coupled to the user interface element detects when the lever is moved, sending a signal to the firmware state machine. At least one field-effect transistor switch is coupled between the air gap device and the downstream load in response to a signal from the firmware state machine.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a simplified diagram of a first embodiment of a circuit breaker in accordance with the present disclosure having electronics and a user interface configured to control normally OFF field-effect transistors and a solenoid in mechanical communication with an airgap device that controls power between a line and a load.

FIG. 2 is a simplified diagram of a second embodiment of the circuit breaker in accordance with the present disclosure having electronics and the user interface configured to control normally ON field-effect transistors and the solenoid in mechanical communication with the airgap device that controls power between a line and a load.

FIG. 3 is a simplified diagram of a third embodiment of the circuit breaker in accordance with the present disclosure having electronics and the user interface configured to control normally ON field-effect transistors and further control opening airgap contacts off on a power loss event.

FIG. 4 is a diagram depicting exemplary elements of electronics configured to control the circuit breaker.

FIG. 5 is a signal diagram detailing the operation of the present embodiments.

FIG. 6 is a diagram of firmware states of a firmware state machine that is configured in accordance with the present disclosure.

FIG. 7 is a diagram of physical states that are realized by the firmware state machine.

FIG. 8 is a diagram of firmware states of a firmware state machine without a FAULT state that is configured in accordance with the present disclosure.

FIG. 9 is a diagram of physical states that are realized by the firmware state machine without a FAULT state implementation.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

A lever activated switch is generally used with the typical mechanical miniature circuit breaker, but rocker switch and push button switch configurations are available. In some breakers, the “TRIP” and “OFF” states are made common to a lever down position to provide two overall states without having a middle lever position. The lever activated switch and associated mechanical assembly usually takes up most of the space allocated to the breaker, as the mechanical assembly needs to connect three mechanisms of control to an air gap device with contacts, and to store a significant amount of energy provided by a stiff spring to open the contacts of the air gap device quickly and minimize degradative effects of arcing during normal operation or upon opening after a fault event. A Solid-State Circuit breaker replaces the bulky internal mechanism with electronic elements (current sensing and solid-state semiconductors) used to replicate the interruption functionally of the typical thermal/magnetic trip unit, and a solenoid used to control an airgap providing galvanic isolation.

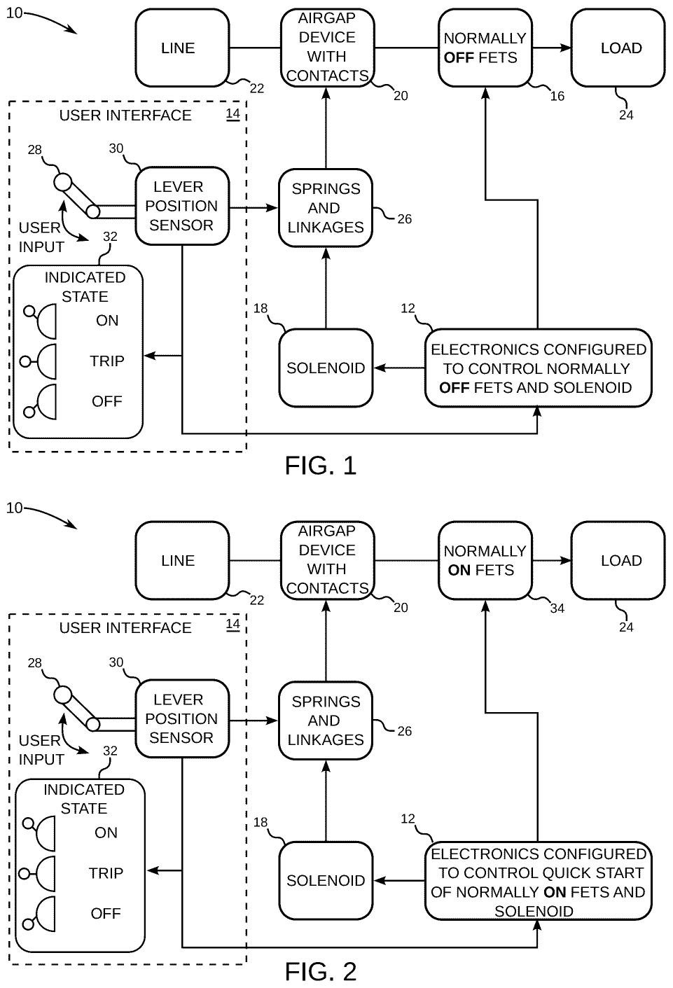

FIG. 1 is a simplified diagram of a first embodiment of a circuit breaker 10 structured in accordance with the present disclosure. The circuit breaker 10 includes electronics 12 and a user interface 14 configured to control normally OFF field-effect transistors (FETs) 16 and a solenoid 18 that is in mechanical communication with an airgap device 20 that controls power between a line 22 and a load 24. The mechanical communication between the solenoid 18 and the airgap device 20 may be accomplished using springs and linkages 26. The addition of the electronics 12 and the normally OFF FETs 16 adds space and thermal constraints, with the former being partially relieved by reduced size and requirements of typical mechanisms. For example, the springs and linkages 26 have fewer parts and require less stored energy for a trip sequence. It is to be understood that the solenoid 18 may be replaced, in this and other embodiments, by another electromagnetic switch type such as a contactor or relay without exceeding the scope of the present disclosure.

In the embodiment depicted in FIG. 1, the user interface 14 has a lever 28 that is configured as a user interface (UI) element. The lever 28 may be mechanically coupled to the springs and linkages 26. A lever position sensor 30 is communicatively coupled to the electronics 12 and a visual indicator 32.

At least one challenge with scaling the first embodiment of circuit breaker 10 to realize that a miniature circuit breaker form factor is related to thermal performance. The power density is relatively too high for the thermal environment of a typical enclosed circuit breaker panel.

In this regard, FIG. 2 is a simplified diagram of a second embodiment of the circuit breaker in which the electronics 12 and the user interface 14 are configured to control normally ON FETS 34 and the solenoid 18 in mechanical communication with the airgap device 20 that controls power between the line 22 and the load 24. The normally ON FETS 34 may be junction FETs (JFETs) that have a relatively low on-resistance, which eases the thermal environment. The challenge presented by employing the normally ON FETS 34 is retaining safety on startup from power loss or during a first installation of the circuit breaker 10 when the contacts of the air gap device 20 are closed on to a short circuit. For example, normally ON FETS 34 would prevent a power supply unit from starting in order to initiate an opening event by way of the solenoid 18 or the normally ON FETS 34.

One solution to address this issue is an architecture where the normally ON FETS 34 are forced to behave like normally OFF FETS 16 at startup, regardless of line conditions, including short circuit. This design not only provides a user interface similar to mechanical circuit breakers but also reduces thermal dissipation enough to make a miniature form factor potentially feasible.

An SSCB architecture with normally ON FETs and employing quick start configuration would only actuate the contacts of the air gap device 20 by way of the solenoid 18 during trip sequences.

Another method of mitigating this startup safety concern is by opening the contacts air gap device every time power is lost, allowing the power supply unit to start before reclosing, as shown in FIG. 2. Although this provides compatibility with using the lower resistance normally ON FETS 34, it also necessitates changes to the user interface 14. For one, there will be a new “POWER LOSS” state which is transient, as the electronics 12 will enter and exit this state as required with no user input. If power is lost while the circuit breaker is ON, the contacts of air gap device 20 will be opened with the intention to return to the previous state, which in this case is ON after power is restored.

Addition of an extra solenoid to move the lever 28 or the contacts of the air gap device would take up too much space in an already challenging form factor. Therefore, if it is assumed that the solenoid 18 is used to open the contacts of the air gap device 20 for both breaker-initiated circuit open events power loss and trip sequence, then a lever position for lever 28 should be made common between these states. Herein a new embodiment and another version of the user interface 14 is disclosed, which makes common the “ON”, “TRIP”, and “POWER LOSS” states in a single lever position. A separate status indicator such as a light-emitting diode may be employed to communicate the TRIP state to the user.

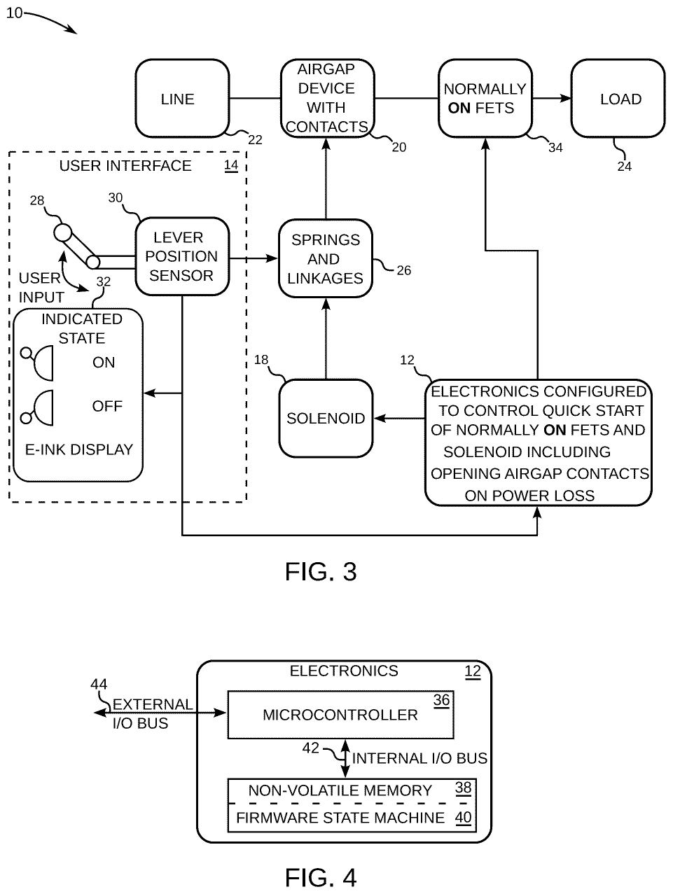

Although TRIP (and power loss) might intuitively be grouped with the OFF state, as shown in FIG. 3, this could lead to problematic scenarios from a safety perspective. For example, consider the previous scenario where instead the breaker is in “POWER LOSS/TRIP/OFF” and will return to the “ON” state when line power returns. If the lever 28 is in the OFF position in this case, the user may feel adequately safe to investigate the downstream circuit for issues without putting a lockout and tagout device (not shown) on the circuit breaker 10. If power is restored during investigations, it could result in the user being exposed to line voltage when they believe the circuit breaker was off. Making common the TRIP/POWER LOSS states provides a novel embodiment of an SSCB using the “Open on power loss” embodiment of FIG. 3, which departs from a traditional circuit breaker user interface with the justification of avoiding unsafe conditions without adding cost/space implications of an additional solenoid.

FIG. 4 is a diagram depicting exemplary elements of the electronics 12 that are configured to control the circuit breaker 10. In this exemplary embodiment, the electronics 12 include a microcontroller 36 and non-volatile memory 38 configured with a firmware state machine 40. The firmware state machine 40 has at least four unique states, including STANDBY, TRIP, OFF, and ON, wherein the firmware state machine 40 is configured to control the solenoid 18 to open or close the air gap device 20 based on a current firmware state and inputs received from the user interface element, such as lever 28. A FET switch made up of the normally OFF FETS 16 or the normally ON FETS 34 is configured to open the contacts of the air gap device 20 in response to a signal from the firmware state machine 40, which is executed by the microcontroller 36. The microcontroller 36 communicates with the non-volatile memory 38 over an internal bus 42. The microcontroller 36 is also configured to send and receive signals over an external input/output (I/O) bus 44 that communicates with the solenoid 18, the lever position sensor 30, the visual indicator 32, and the normally ON FETS 34.

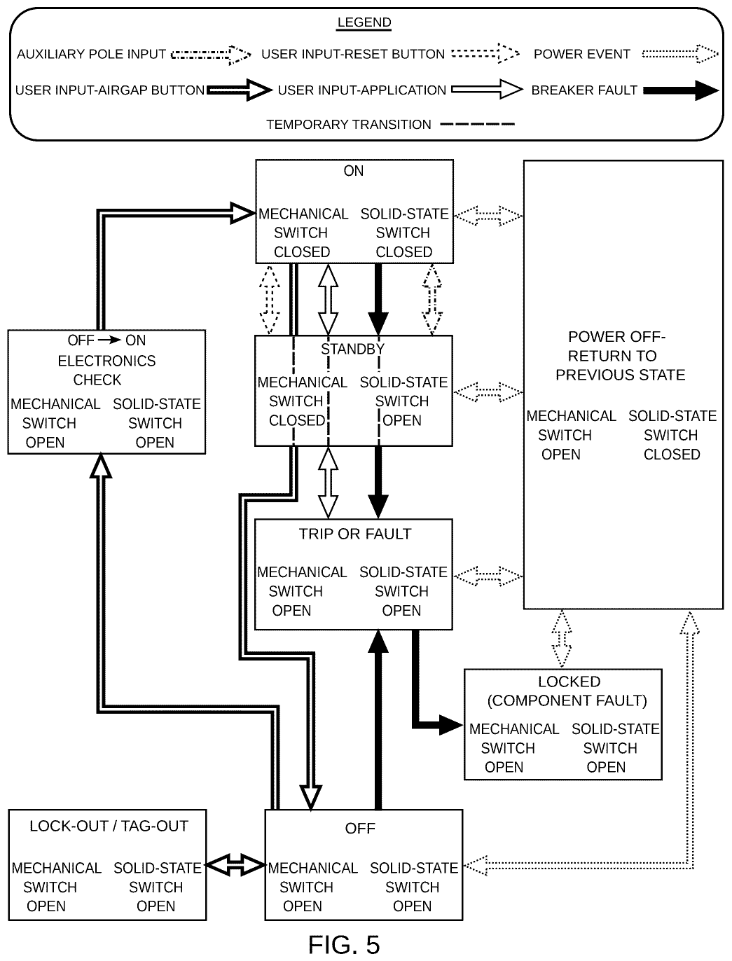

Turning attention to FIG. 5 and as previously discussed, TRIP and POWER LOSS indicate the same lever-up position as ON. However, further information to distinguish between the states is accomplished by additional UI elements, in this case an e-ink display and a red-green-blue light-emitting diode. This embodiment achieves three states (TRIP, ON, and POWER OFF) with use of a single solenoid, while retaining the ability to manually override the air gap device to open (OFF) and add LOTO devices as necessary. This allows compatibility with off-the-shelf LOTO devices with lever-type UIs commonly used across existing products. Alternative UI elements are, for example, a UI using a set of push buttons that may require a custom LOTO product but may provide a more intuitive user experience. Whereas a customer interacting with the UI may be accustomed to seeing lever-style products TRIP in the off or middle lever position and may be confused when TRIP is signaled with the lever 18 in the lever-up position, that preconception would not necessarily be a factor when using an alternative UI element such as push buttons.

In another embodiment, the lever 28 (i.e., the UI element) of the circuit breaker 10 can only interact with the mechanism in a way that opens the contacts of the air gap device 22, meaning that user input never directly closes the contacts of the air gap device 22. Instead, intent to close the contacts of the air gap device 20 by moving the lever to the ON position is detected by the lever position sensor 30, which in turn sends a position signal to the electronics 12, and the state listed as “OFF→ON electronics check” is entered. If a circuit protected by the circuit breaker 10 is unsafe, the contacts of the air gap device 20 will not be closed, and if they are to be closed, the mechanical/solid-state timing interaction may be handled correctly to minimize contact wear and achieve zero volt switching if desired. This allows a permanent lock-out in the event of an internal failure and compatibility with Underwriter Laboratories (UL) requirements that the contacts of the air gap device 20 cannot be held closed in event of a short circuit, without adding additional components. An existing architecture does not have the same functionality but instead uses a second point of travel in the solenoid 18 to reach a state of permanent lockout by increasing a drive pulse. However, the decrease in size of the circuit breaker 10 makes this solution impractical. If the quick start functionality is instead implemented, a small trip solenoid is sufficient to meet all these functionality requirements and would take up less space than the bistable relay currently used.

By way of illustration of the transition from ON to OFF, which occurs when the user moves the lever down, the lever 18 is laid out such that it moves a manual override toggle of an off-the-shelf bistable relay (not shown). To begin, the toggle is down, which correlates with closed contacts of air gap device 20, but as the toggle is moved up, it changes to the OFF state in which the contacts of the air gap device are closed. Before the contacts of the air gap device 20 actually open, the intention is sensed and the normally ON FETS 34 are used to open the circuit to prevent arcing. In the OFF position, the electronics 12 cannot close the contacts of the air gap device 20, even in the event of a misfire of the solenoid 18.

Another illustration demonstrates what happens when the external lever is moved back up by the user. Instead of the lever's movement directly actuating the contacts of the air gap device 22 by way of an override toggle, it simply removes the impediment and indicates to the electronics by way of the lever position sensor 30 that the lever 28 has been moved up, such that the electronics 12 can drive the solenoid 18 closed when or if desired and safe.

A feature of the embodiment shown in the flow diagram of FIG. 5 is that from the user perspective, whether the mechanical switch opens or not in the standby state is not particularly relevant. Additionally, there is no direct indication on the e-ink as to the state of the mechanical switch. This suggests an operating method where the mechanical switch is always opened on entering standby state. This then gives a list of states where the only difference is the position of the lever and the firmware's ability to return to ON:
STANDBY
TRIP
OFF-LOCKOUT
FAULT

The OFF and LOCKOUT states are with the lever 28 in the down position. The electronics 12 has no means of raising the lever 28, which also provides a direct mechanical lockout to the electromechanical switch element, which in this case is airgap device 20.

Putting the lever 28 to the OFF state clears any trips. This suggests an alternate UI with only a lever, and at its simplest a “STANDBY” light. The user clearing the trip puts the circuit breaker 10 into the ON state, or alternately puts the circuit breaker 10 into the ON state or the STANDBY state.

In a traditional circuit breaker, a user would clear any FAULT states by moving the lever 28 to the OFF state and then back to the ON state. This transition from OFF to ON would reset the mechanical element. Another option possible with this implementation is to allow a remote user to clear the FAULT state without having to physically move the lever. With an electrically controlled mechanical element, the user would request a reset of the fault. This request could be through a mobile app or other software-based application. This would allow the user to be outside of the arc flash boundary as defined by NFPA 70E, creating a safer method for restarting faulted systems.

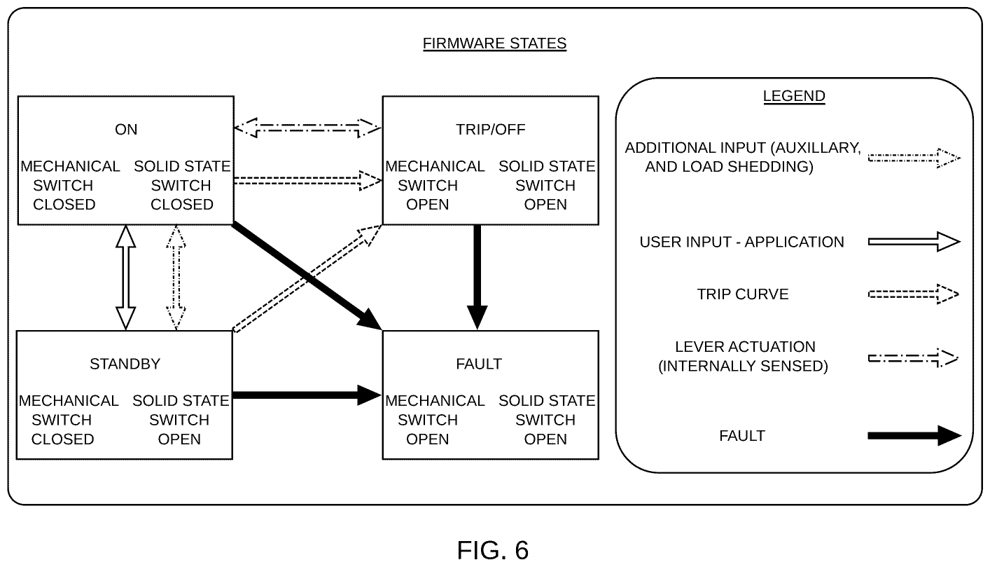

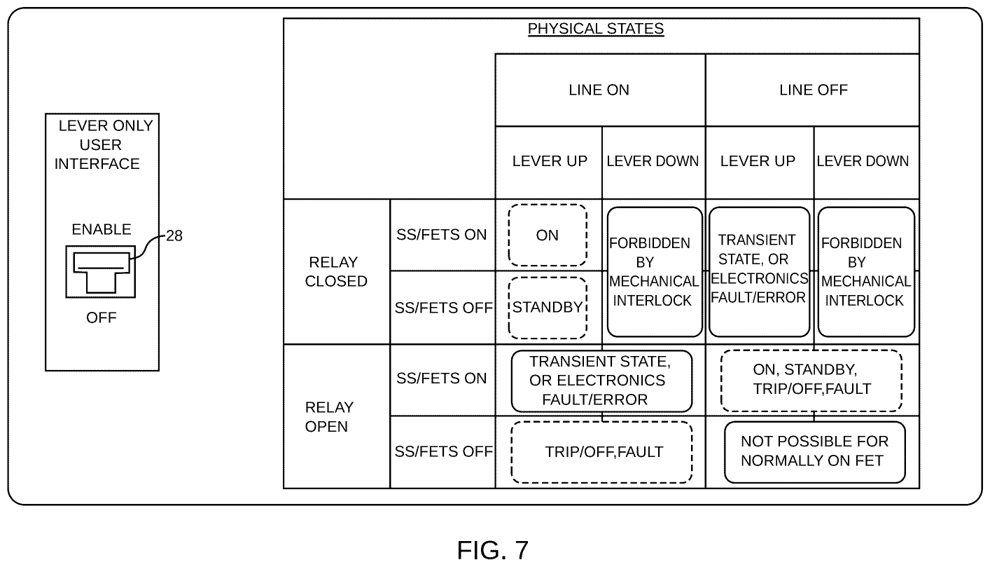

FIG. 6 is a diagram of firmware states of a firmware state machine that is configured in accordance with the present disclosure. This embodiment of the open-on-power-loss architecture only requires a single UI element lever 28 to operate. The “Firmware States” diagram shows four unique states that need to be identified and stored in non-volatile memory on the electronics 12, as well as different events that would initiate a change between them. FIG. 7 depicts other possibilities of “Physical States” of the circuit breaker 10 exist due to permutations of lever position, line condition, air gap device/relay status, and FET status. These are reduced to four firmware states by combining states which are equivalent from a firmware perspective and by ignoring states which are either forbidden/mechanically impossible or not necessary to represent with a firmware state. Note that some states represented in FIG. 7 are used for diagnostics or entered only if a system fault has been encountered.

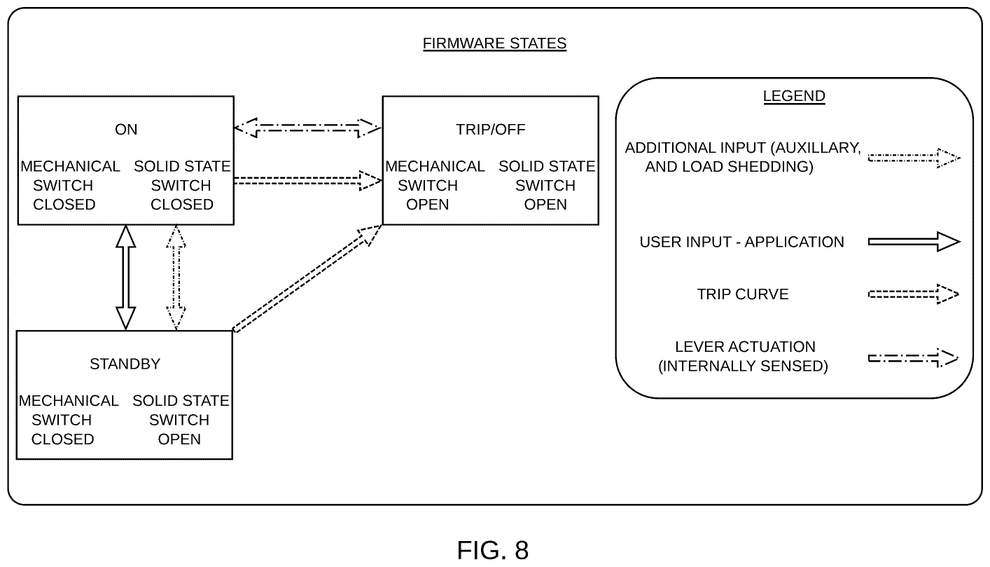

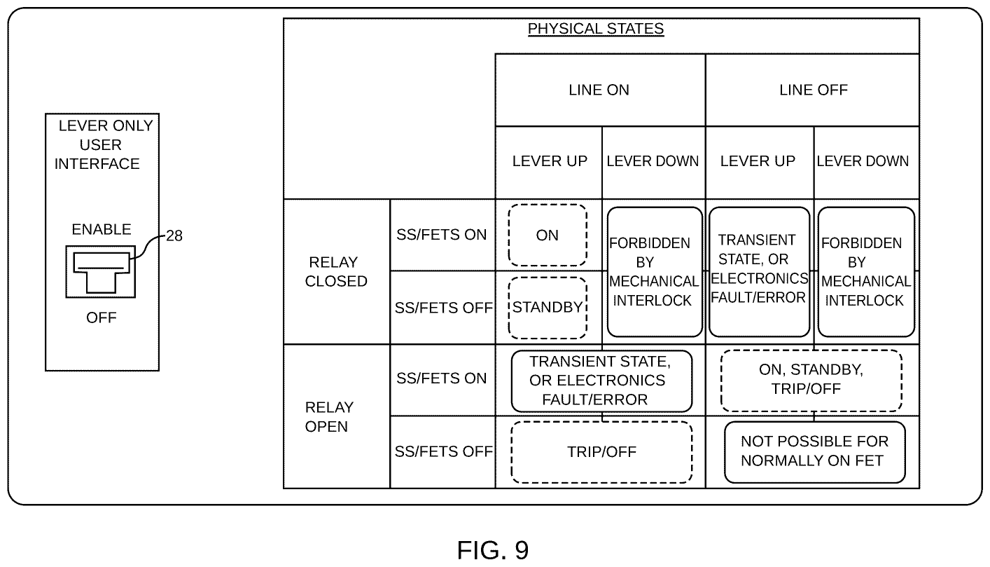

FIG. 8 is a diagram of firmware states of a firmware state machine without a FAULT state that is configured in accordance with the present disclosure. This embodiment of the open-on-power-loss architecture only requires a single UI element lever 28 to operate. The “Firmware States” diagram shows four unique states that need to be identified and stored in non-volatile memory on the electronics 12, as well as different events that would initiate a change between them. FIG. 9 depicts that other possibilities of “Physical States” of the circuit breaker 10 exist due to permutations of lever position, line condition, air gap device/relay status, and FET status. These are reduced to four firmware states by combining states which are equivalent from a firmware perspective and by ignoring states which are either forbidden/mechanically impossible or not necessary to represent with a firmware state.

One notable example is that the breaker and its firmware do not need to recognize a unique “OFF” state, which is a purely UI state entered/exited by way of the lever 18 and that overrides all forms of electronics control by way of a direct mechanical interlock to the air gap device 20. Because it may be desirable to open the normally ON FETS 34 in this state, it has been grouped with TRIP. When the lever 18 is returned to the upper (ENABLE) position after being down (OFF), trip flags and standby controls will be reset to return to the ON state. However, in the event of a breaker fault (in the FAULT state), the electronics 12 will not re-close the contacts of the air gap device 20. No methods of leaving the FAULT state have been listed in either FIG. 8 or FIG. 9, but if desired a “repair code” or similar could allow the circuit breaker 10 to return to a functioning state where possible. In this embodiment, sensing the position of level 28 or sensing when it changes position can fulfill all required UI functions without including ancillary UI elements or additional internal sensors. This internal sensing functionality is listed with dot-dashed outlined arrows as Lever Actuation in FIG. 8.

The STANDBY state could also be slightly abstracted, in that one could choose to open the contacts of the air gap device 20 or not when the STANDBY state is entered. Currently, the contacts of the air gap device 20 remain closed in STANDBY, which reduces mechanical wear of the contacts.

The FAULT state is omitted from FIG. 8 and FIG. 9 because the FAULT state is not required for functionality but rather is a feature for creating safe failure conditions based on the failure mode and effects analysis, where component status is sensed to detect whether everything is functioning correctly. Thus, simpler versions of various embodiments could remove the FAULT state altogether. This could be accommodated in the failure mode and effects analysis through other design mitigations, for example, avoiding single points of failure through component duplication or similar. Note that some states represented in FIG. 9 are used for diagnostics or entered only if a system fault has been encountered.

The rough overall size of the circuit breaker 10 is 5 inches×2.75 inches×1 inch. The 5-inch length allows fitment into most standard cabinets while maintaining required cable bend radius for a 40A-50A product (and 60A using high-temperature insulation wiring). The 1-inch thickness is also standard for residential cabinets. Reducing the SSCB form factor is both as a way to access substantial new markets. One circuit breaker product is approximately 8 inches×6 inches×4 inches, so the disclosed circuit breaker is less than 10% of the volume of the previous product. These are all rough estimates not accounting for the complex shapes of these products (simplified to cuboids). However, it is to be understood that the disclosed circuit breaker may be configured to fit within a volume between 12 cubic inches and 14 cubic inches.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A circuit breaker comprising:
a user interface element configured to receive input from a user;
an air gap device having contacts that can be electrically opened and closed to interrupt or connect electrical power to a downstream load;
a firmware state machine having at least four unique states, including STANDBY, TRIP, OFF, and ON, wherein the firmware state machine is configured to open or close the contacts of the air gap device based on the current firmware state and inputs received from the user interface element; and
at least one field-effect transistor (FET) switch coupled between the air gap device and the downstream load, wherein the FET switch is configured to open or close in response to a signal from the firmware state machine and when opening the FET switch ensure that the FET switch interrupts the flow of current prior to opening the air gap device.

2. The circuit breaker of claim 1 wherein the at least one FET is a normally ON type.

3. The circuit breaker of claim 1 wherein the at least one FET is a normally OFF type.

4. The circuit breaker of claim 1 wherein a user can remotely reset the circuit breaker from the TRIPPED state to the ON state by way of the user interface.

5. The circuit breaker of claim 1 wherein the user interface element comprises a lever that can be moved between at least two positions, including an up position and a down position, wherein the user interface element is configured to send signals to the firmware state machine indicating the position of the lever.

6. The circuit breaker of claim 5 further comprising a sensor coupled to the user interface element and configured to detect when the lever is moved from one position to another, and to send a signal to the firmware state machine indicating that the lever has been moved.

7. The circuit breaker of claim 6 wherein the sensor is a microswitch.

8. The circuit breaker of claim 1 further comprising:
breaker electronics configured with the firmware state machine; and
non-volatile memory in communication with the breaker electronics, wherein the firmware state machine is configured to store at least one of the unique states in the non-volatile memory.

9. The circuit breaker of claim 8 further comprising:
a microcontroller, wherein the microcontroller is programmed to execute instructions based on configurations stored in non-volatile memory on the breaker electronics, including instructions for controlling the solenoid and FET switch based on the current firmware state and inputs received from the user interface element, wherein the solenoid is controllably coupled to the microcontroller and configured to open or close the air gap device when driven by the microcontroller; and
at least one sensor or switch coupled to the air gap device, solenoid, or other components of the circuit breaker, wherein the sensor or switch is configured to send signals to the microcontroller indicating the status of the air gap device, solenoid, or other components.

10. The circuit breaker of claim 9 further comprising:
a power supply, wherein the power supply is configured to provide power to the microcontroller, solenoid, FET switch; and
at least one input/output (I/O) interface, wherein the I/O interface is configured to receive inputs from the user interface element and send signals to the microcontroller based on the current firmware state.

11. The circuit breaker of claim 1 further comprising a visual indicator that shows the current firmware state.

12. The circuit breaker of claim 11 wherein the visual indicator is an e-ink display.

13. The circuit breaker of claim 1 wherein the circuit breaker is configured to fit within a volume that is between 12 cubic inches and 14 cubic inches.

14. A method for controlling a circuit breaker, the method comprising:
providing an air gap device having contacts that can be electrically opened and closed to interrupt or connect electrical power to a downstream load;
implementing a firmware state machine having at least four unique states (STANDBY, TRIP, OFF, ON), wherein the firmware state machine is configured to control the solenoid and open or close the air gap device based on the current firmware state and inputs received from a user interface element;
providing the user interface element configured to send signals to the firmware state machine indicating a user's input of a selectable one of the at least four unique states;
coupling a sensor to the user interface element; and
configuring the sensor to detect the user's input and sending a signal to the firmware state machine indicating the user's selection; and
coupling at least one field-effect transistor (FET) switch between the air gap device and the downstream load, wherein the FET switch is configured to open to open or close in response to a signal from the firmware state machine and when opening the FET switch ensure that the FET switch interrupts the flow of current prior to opening the air gap device.

15. The method for controlling the circuit breaker of claim 14 wherein the at least one FET is a normally ON type.

16. The method for controlling the circuit breaker of claim 14 wherein the at least one FET is a normally OFF type.

17. The method for controlling the circuit breaker of claim 14 wherein the user interface element is a lever configured to be moved between at least two positions.

18. The method for controlling the circuit breaker of claim 17 further comprising detecting the position of the lever by way of the sensor.

19. The method for controlling the circuit breaker of claim 17 wherein the sensor is a microswitch.

20. The method for controlling the circuit breaker of claim 15 wherein the circuit breaker further comprises a visual indicator configured to indicate to a user a present state of the circuit breaker.

21. The method for controlling the circuit breaker of claim 20 wherein the visual indicator is an e-ink display.

22. The method for operating the circuit breaker of claim 14 comprising:
providing the circuit breaker with breaker electronics and a non-volatile memory;
operating the circuit breaker using the firmware state machine to manage at least one unique state of the circuit breaker; and
storing the at least one unique state in the non-volatile memory by the firmware state machine.

23. The method for controlling the circuit breaker of claim 14 comprising:
providing the circuit breaker with a microcontroller, non-volatile memory, a solenoid, and at least one sensor or switch;
storing instructions in the non-volatile memory for controlling the solenoid and FET switch based on the current firmware state and inputs received from the user interface element;
executing the stored instructions on the microcontroller to control the circuit breaker's components, including driving the solenoid to open or close the air gap device;
receiving signals from the at least one sensor or switch indicating the status of the air gap device, solenoid, or other components; and
using the received signals to inform the operation of the circuit breaker.
